(19) United States
(12) Patent Application Publication
(10) Pub. No.: US 2026/0129975 A1
(43) Pub. Date: May 7, 2026

(54) Flexible Hybrid Nanosheet Standard Cell Architecture

(71) Applicant: Apple Inc., Cupertino, CA (US)

(72) Inventors: Emre Alptekin, Santa Clara, CA (US); Xin Miao, Saratoga, CA (US)

(21) Appl. No.: 19/340,153

(22) Filed: Sep. 25, 2025

Related U.S. Application Data
(60) Provisional application No. 63/698,920, filed on Sep. 25, 2024.

(51) Int. Cl. H10D 89/10; H10D 84/83

(52) U.S. Cl. CPC H10D 89/10; H10D 84/832

(57) ABSTRACT

Various implementations related to the use of nanosheet transistors formed on a substrate are disclosed. A nanosheet transistor includes an active region with a width that defines an active device width for the transistor. Hybrid cell structures are disclosed that implement a column of template cells abutting a column of flexible height cells. Flexible height cells may be placed at specified locations in a design logic to provide improved performance or power optimization at the specified locations.

### PRIORITY CLAIM

The present application claims priority to U.S. Provisional App. No. 63/698,920, entitled “Flexible Hybrid Nanosheet Standard Cell Architecture,” filed Sep. 25, 2024, the disclosure of which is incorporated by reference herein in its entirety.

### BACKGROUND

### Technical Field

Embodiments described herein relate to transistor structures for semiconductor devices. More particularly, embodiments described herein relate to structures and designs for integrated circuit cells with nanosheet transistors having flexible heights.

### Description of the Related Art

Nanosheet (e.g., gate-all-around) transistors are increasingly being utilized in integrated circuits. Nanosheet transistors may have more effective characteristics for turning on/off the transistors versus planar FETs or FinFETs due to the increase in gate control of the channel provided by the geometry of the nanosheet transistor design. The increased effectiveness in turning the transistors on or off may provide leakage reduction and better power utilization (e.g., voltage reduction) for integrated circuits utilizing nanosheet transistors. Nanosheet transistors may have a more complex design than planar FETs or FinFETs. As the design of integrated circuits evolves, more avenues for utilization of the more complex design of nanosheet transistors may be contemplated.

### BRIEF DESCRIPTION OF THE DRAWINGS

Features and advantages of the methods and apparatus of the embodiments described in this disclosure will be more fully appreciated by reference to the following detailed description of presently preferred but nonetheless illustrative embodiments in accordance with the embodiments described in this disclosure when taken in conjunction with the accompanying drawings in which:

FIG. 1 depicts a top-view representation of a device having cells with standard (equal) heights, according to some embodiments.

FIG. 2 depicts a top-view representation of a device having two cells with two different (tall/short) cell heights, according to some embodiments.

FIG. 3 depicts a top-view representation of a column of cells having tall/short heights with variable width power grid routes positioned above the cells (vertically above relative to substrate), according to some embodiments.

FIG. 4 depicts a top-view representation of a logic block having a tall to short cell ratio of 2:2 from FIG. 3, according to some embodiments.

FIG. 5 depicts a top-view representation of a logic block having a tall to short cell ratio of 2:1, according to some embodiments.

FIG. 6 depicts a top-view representation of a column of cells having tall/short heights with the 2:1 tall to short cell ratio of FIG. 5, according to some embodiments.

FIG. 7 depicts a top-view representation of a column of cells having tall/short heights with fixed width power grid routes positioned above the cells (vertically above relative to substrate), according to some embodiments.

FIG. 8 depicts a top-view representation of a column of cells having tall/short heights with fixed width power grid routes positioned above the cells and different signal routes spacing for tall and short cells, respectively, according to some embodiments.

FIG. 9 depicts a top-view representation of another column of cells having tall/short heights with fixed width power grid routes positioned above the cells and different signal routes spacing for tall and short cells, respectively, according to some embodiments

FIG. 10 depicts a top-view exploded representation of a column of cells in a transistor region having a tall cell and a short cell with two metal routing layers that are positioned above the transistor region and column where the pitch and number of signal routes in both layers is determined by the height of the underlying cell, according to some embodiments.

FIG. 11 depicts a top-view representation of a logic sub-block having three columns of cells with tall and short height cells and fixed width power grid routes across the columns of cells, according to some embodiments.

FIG. 12 depicts a plan view representation of a device having logic sub-blocks with different ratios of tall/short cells in the logic sub-blocks showing that the logic sub-blocks can have any ratio of tall/short cells regardless of location of logic sub-block in device, according to some embodiments.

FIG. 13 depicts a top-view representation of a device having a column of two template cells of equal height abutting a column of one double height cell, according to some embodiments.

FIG. 14 depicts a top-view representation of a device having a column of two template cells of equal height abutting a column of two flexible cells with different heights, according to some embodiments.

FIG. 15 depicts a top-view representation of the device of FIG. 14 with power and signal routing positioned vertically above the device (relative to the substrate), according to some embodiments.

FIG. 16 depicts a top-view representation of a device having a column of two flexible cells with different heights positioned between (and abutting) two columns of two template cells of equal heights, according to some embodiments.

FIG. 17 depicts a top-view representation of a device having two columns of two flexible cells with different heights positioned between (and abutting) two columns of two template cells of equal height, according to some embodiments.

FIG. 18 depicts a top-view representation of a device having a column of three template cells of equal heights abutting a column of two flexible cells with different heights, according to some embodiments.

FIG. 19 depicts a top-view representation of a device having a column of three template cells of equal heights abutting a column of three flexible cells with different heights, according to some embodiments.

FIG. 20 depicts a top-view representation of a device having a column of three template cells of equal heights abutting a column of three flexible cells with two flexible cells having equal heights and the third cell having a different height, according to some embodiments.

FIG. 21 is a block diagram of one embodiment of an example system.

Although the embodiments disclosed herein are susceptible to various modifications and alternative forms, specific embodiments are shown by way of example in the drawings and are described herein in detail. It should be understood, however, that drawings and detailed description thereto are not intended to limit the scope of the claims to the particular forms disclosed. On the contrary, this application is intended to cover all modifications, equivalents and alternatives falling within the spirit and scope of the disclosure of the present application as defined by the appended claims.

### DETAILED DESCRIPTION OF EMBODIMENTS

The present disclosure is directed to implementations of nanosheet transistors formed on a substrate. In certain embodiments, a nanosheet transistor includes an active region with a width that defines an active device width for the transistor. For certain embodiments of nanosheet transistors, the width of the active region corresponds to the width of nanosheet fins. In various embodiments, nanosheet fins are made of silicon, another semiconductor, or a combination of semiconductors that pass through the structure (e.g., the material) of a gate of the transistor. In some embodiments, nanosheet fins are relatively thin (in the vertical dimension perpendicular to the substrate), rectangular regions (e.g., sheets) of semiconductor material that are aligned parallel to the substrate (e.g., the horizontal planes of the nanosheet fins are parallel to the horizontal plane of the substrate). A nanosheet transistor typically includes multiple nanosheet fins passing through a gate.

As used herein, the term “standard cell” refers to a group of transistor structures, passive structures, and interconnect structures formed on a substrate to provide logic or storage functions that are standard for a variety of implementations. For example, an individual standard cell may be one cell in a library of multiple cells from which various suitable cells may be selected to implement a specific cell design. As further example, a standard cell may be a cell design that is created (e.g., designed) and then the cell design is implemented multiple times for generating integrated circuit devices via, for instance, synthesis or automated flows. Integrated circuit cells may also include custom circuit design cells that are individually designed for a particular implementation. Embodiments of circuit design cells described herein may be implemented in various implementations of logic integrated circuits or memory integrated circuits.

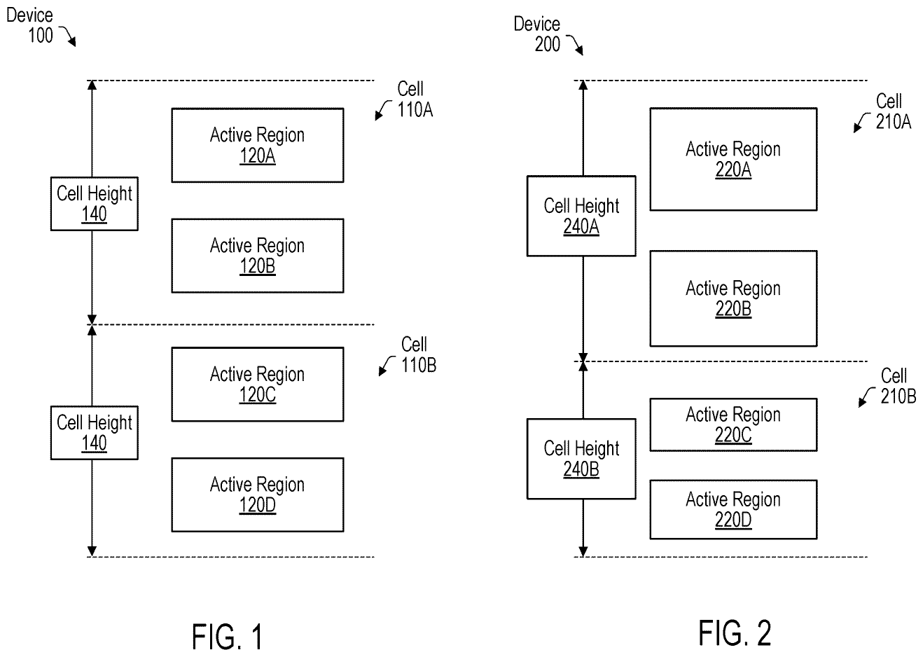

Standard cells for nanosheet transistors typically include multiple cells distributed across a height for a standard cell. Thus, the standard cell includes multiple individual cells. Many standard cell architectures for nanosheet transistors are based off uniform nanosheet cell sizing where the active regions in the individual cells have uniform widths across the cells. FIG. 1 depicts a top-view representation of a device having cells with standard (equal) heights, according to some embodiments. In the illustrated embodiment, device 100 is a standard cell with two cells 110A, 110B. Cells 110A and 110B have standard cell heights 140 that are substantially the same. Further, active regions 120A-D have uniform widths in the cell height direction to provide the uniform spacing and widths across the cell height of device 100. Active regions 120A-D may be either n-type or p-type active regions (e.g., active regions for NFET or PFET devices). In various embodiments, a cell has complementary active regions with a first active region of one type and a second active region of the complementary type. For instance, active region 120A in cell 110A may be a p-type active region while active region 120B is an n-type active region. Having uniform widths across the cells, however, limits the potential for optimization of performance and/or power in standard cells.

Nanosheet processing technologies allow for variations in the widths of active regions between different cells. Accordingly, hybrid standard cells may be manufactured where different cells have different cell heights within a standard cell height. FIG. 2 depicts a top-view representation of a device having two cells with two different (tall/short) cell heights, according to some embodiments. In the illustrated embodiment, device 200 is a standard cell height device with a tall cell 210A and a short cell 210B. Cell 210A has cell height 240A while cell 210B has a shorter cell height 240B. The differences in cell heights allow active regions 220A, 220B in cell 210B to be wider in the cell height direction than active regions 220C, 220D in cell 210B. With the larger cell height 240A for cell 210A, cell 210A becomes the faster cell. Such hybrid standard cells as device 200 may provide better performance and power by including a combination of taller cells (larger active region widths) for better performance and shorter cells for power optimization.

While hybrid standard cell architectures that include combinations of tall and short cells provide better performance properties and better power optimization for various logic designs, a drawback of current hybrid standard cell architectures is the architectures may have predetermined ratios of tall to short cells (e.g., 1:1, 2:2, 1:2, etc.) that have to be carried across an entire logic block. For instance, in current implementations of hybrid standard cell libraries, power grid (PG) routes have widths that vary based on the cells in abutment at the PG routes.

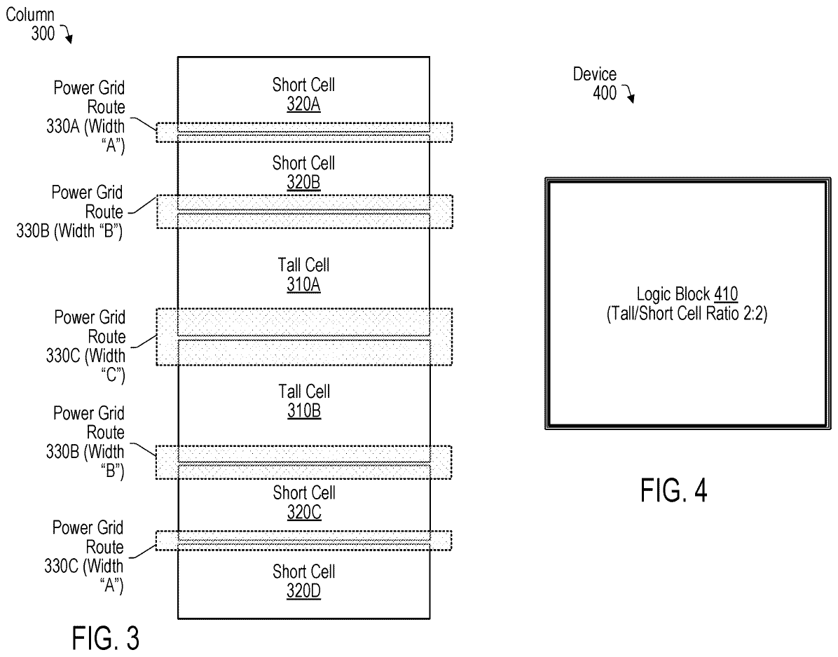

FIG. 3 depicts a top-view representation of a column of cells having tall/short heights with variable width power grid routes positioned above the cells (vertically above relative to substrate), according to some embodiments. In the illustrated embodiment, column 300 includes a combination of tall cells 310A-B and short cells 320A-D in a 2:2 ratio. With the 2:2 tall to short cell ratio, there are three different abutments-short/tall, tall/tall, and short/short. These different types of abutments result in power grid routes with different widths at the abutments. For instance, the abutment of short cell 320A and short cell 320B and the abutment of short cell 320C and short cell 320D both result in power grid route 330A (width “A”). The abutments of short cell 320B and tall cell 310A and tall cell 310B and short cell 320C both result in power grid routes 330B (width “B”). The abutment of tall cell 310A and tall cell 310B results in power grid route 330C (width “C”). Thus, different power grid route widths are encountered on different sides of cells that are transition cells. It should be noted that power grid routes 330A-C are positioned in layers above or below the cells (e.g., in a first metal layer above the transistor region of the cells in a vertical direction above a substrate).

In such embodiments where the power grid route widths are determined based on the sizes of the cells abutting the transition, any change to the ratio of tall/short cells in a library requires different cell characterization and a new cell library to be created. FIG. 4 depicts a top-view representation of a logic block having a tall to short cell ratio of 2:2 from FIG. 3, according to some embodiments. In the illustrated embodiment, device 400 includes logic block 410 with a plurality of tall to short cells laid out in a ratio of 2:2. Because the PG route width varies between different cell transition abutments, the entire logic block is required to have the ratio of 2:2 and each cell (tall or short) is characterized according to the PG route widths on either side of the cell (in the row direction).

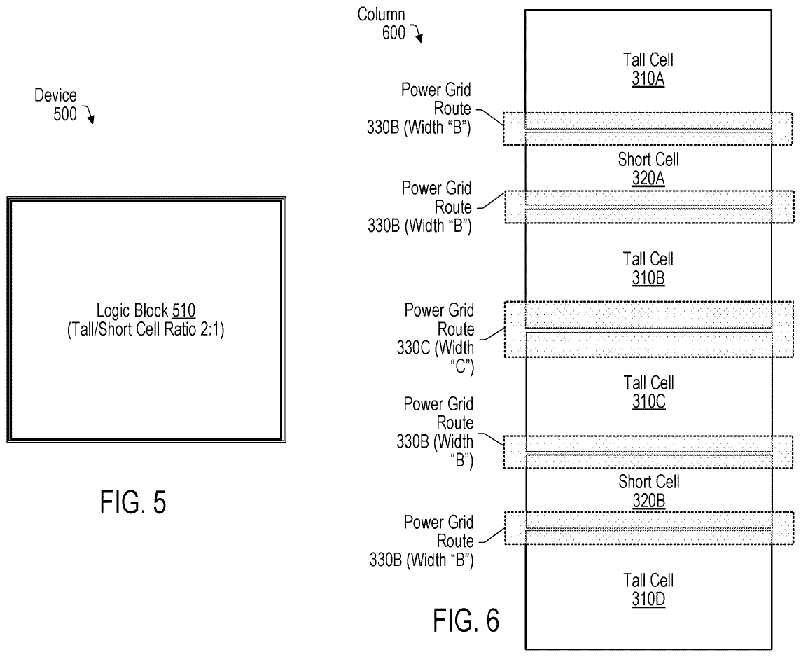

With the restriction on the entire logic block, any desired change in the tall to short cell ratio means that the cells need to be recharacterized based on the changes in PG route widths that result from the change in tall to short cell ratio. FIG. 5 depicts a top-view representation of a logic block having a tall to short cell ratio of 2:1, according to some embodiments. In the illustrated embodiment, device 500 includes logic block 510 with a plurality of tall to short cells laid out in a ratio of 2:1. FIG. 6 depicts a top-view representation of a column of cells having tall/short heights with the 2:1 tall to short cell ratio of FIG. 5, according to some embodiments. In the illustrated embodiment, column 600 includes a combination of tall cells 310A-D and short cells 320A-B now in a 2:1 ratio. With the 2:1 tall to short cell ratio, there are two different abutments—short/tall and tall/tall—rather than the three different abutments of FIG. 3. The two different abutments now only include power grid route 330B (width “B”) and power grid route 330C (width “C”) and there are no power grid routes with width “A” from FIG. 3. With the change in the row of short cells to tall cells going from a 2:2 ratio to a 2:1 ratio, the power grid route widths at cell transitions also change. Accordingly, the short cells in logic block 510 (short cell 320A and short cell 320B in FIG. 6) now need to be recharacterized according to the new abutments to change the design from logic block 410 (shown in FIG. 4). The recharacterization further requires a different cell library to be made to accommodate the changes. Thus, any variation on the predetermined ratio would require a different cell library to be developed, limiting the flexibility in design logic.

The present disclosure contemplates improvements in the design of cell blocks and power grid routes to provide row-based flexibility in device design logic. For instance, tall/short standard cells may be defined in a way to be completely independent cells with respect to height regardless of abutment of the cells and transitions by placing constraints on the power grid route widths. In certain embodiments, the power grid route width is maintained at a specified width regardless of the size of the cells bordering the power grid route. Additionally, the power grid route may be centered on the boundary between two neighboring cells. Fixing the power grid route width provides a design logic where the cells bordering the power grid route width can be characterized and then changed (e.g., from tall to short or short to tall) without any need for recharacterization. Accordingly, there is now flexibility in the placement of any number of tall to short cell ratios across a logic block and sub-blocks may have different tall to short cell ratios. In various embodiments, the signal route spacing between power grid routes is varied based on the spacing provided by the power grid routes as determined by the cell height.

Certain embodiments described herein have four broad elements: 1) a standard cell structure of nanosheet active regions with widths in a column direction and lengths in a row direction; 2) a first set of active transistor cells having a first cell height; 3) a second set of active transistor cells having a second cell height, and 4) a metal routing layer having a plurality of power grid routes oriented in a row direction with constant widths in a column direction. In some embodiments, the power grid routes are placed along boundaries between the cells such as at the center of the boundaries between cells. In some embodiments, signal routes are oriented in the row direction with a number of signal routes and a pitch of the signal routes being determined according to the spacing between the power grid routes as determined by the height of the cells under the signal routes.

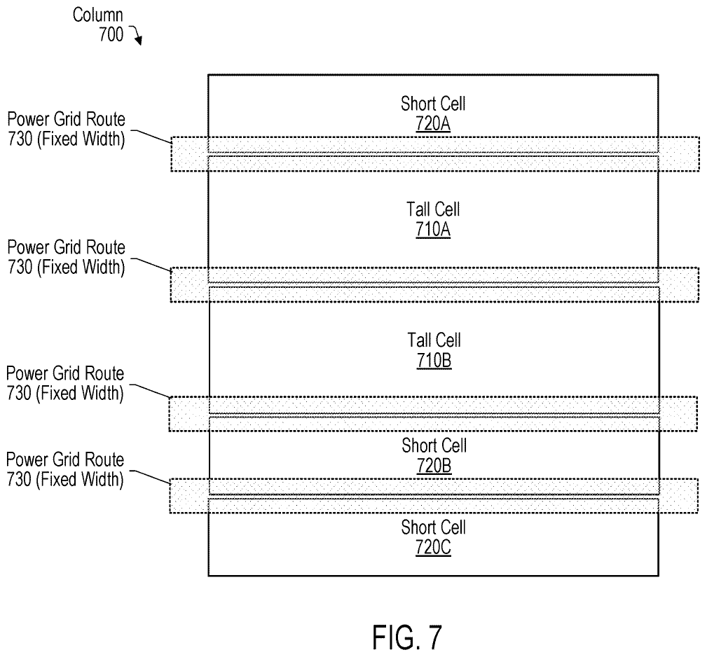

FIG. 7 depicts a top-view representation of a column of cells having tall/short heights with fixed width power grid routes positioned above the cells (vertically above relative to substrate), according to some embodiments. In the illustrated embodiment, column 700 includes a combination of tall cells 710A-B and short cells 720A-C. Power grid routes 730 are fixed width power grid (PG) routes placed at the abutments between the cells. In certain embodiments, power grid routes 730 are centered on the boundaries between the cells. Having fixed width power grid routes 730 at the abutment of any cells within column 700 allows the arrangement of the cells (e.g., locations and/or ratios of tall to short cells) to change without any impact on the characterization of the individual cells.

With fixed width power grid routes 730 in place, changes in placement of tall or short cells now changes the spacing available for signal routes over the cells. The spacing now may change based on the size of the cell only rather than the size of the cell and the width of the adjacent power grid route. For example, tall cells may have one spacing available for signal routes while short cells have a different spacing available for signal routes.

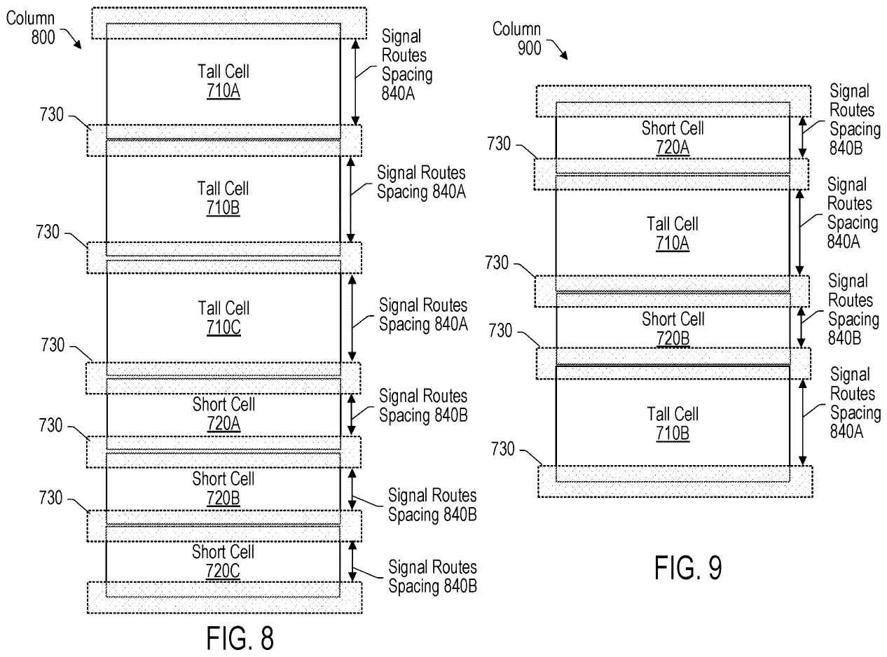

FIG. 8 depicts a top-view representation of a column of cells having tall/short heights with fixed width power grid routes positioned above the cells and different signal routes spacing for tall and short cells, respectively, according to some embodiments. FIG. 9 depicts a top-view representation of another column of cells having tall/short heights with fixed width power grid routes positioned above the cells and different signal routes spacing for tall and short cells, respectively, according to some embodiments. In the illustrated embodiments of FIGS. 8 and 9, columns 800 and 900 include tall cells 710A-C that have signal routes spacing 840A and short cells 720A-C that have signal routes spacing 840B. As shown in the figures, spacing 840A and spacing 840B remain constant regardless of the size of an abutting cell due to the fixed width of power grid routes 730.

With the fixed width power grid routes, the height of the cell (e.g., either tall or short and relative height of tall or short cell) determines the spacing available for signal routes in both the metal layer of the power grid routes and the next metal layer (e.g., metal layer vertically above the power grid metal layer relative to the substrate). In various embodiments, the number of signal routes and/or the pitch of the signal routes is varied based on the spacing available for the signal routes. The number of signal routes and the pitch may also be varied between the different metal layers since there are typically no power grid routes in the higher metal layers.

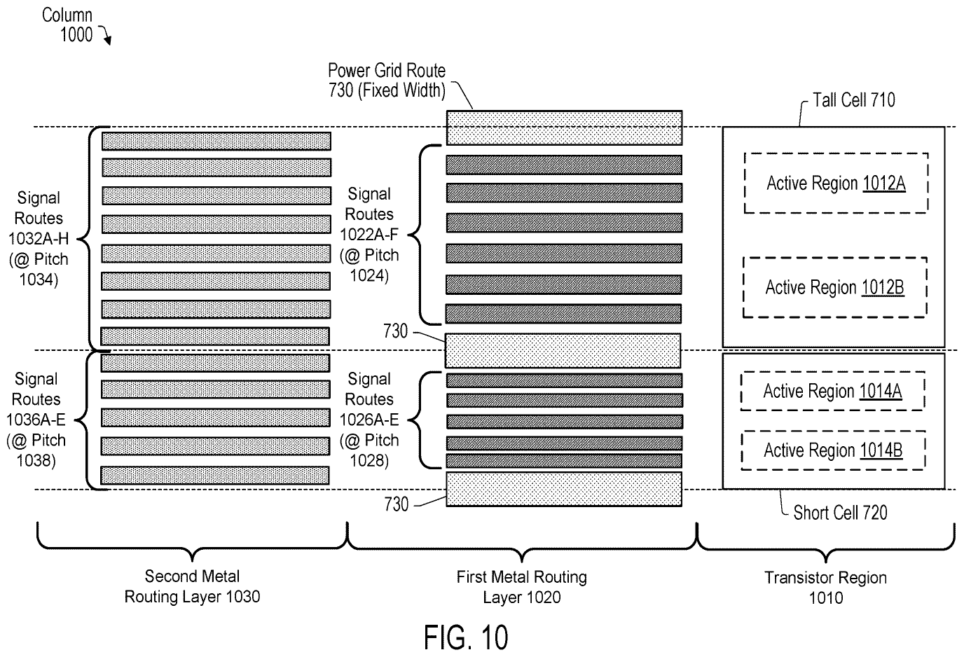

FIG. 10 depicts a top-view exploded representation of a column of cells in a transistor region having a tall cell and a short cell with two metal routing layers that are positioned above the transistor region and column where the pitch and number of signal routes in both layers is determined by the height of the underlying cell, according to some embodiments. In the illustrated embodiment, column 1000 includes transistor region 1010, first metal routing layer 1020, and second metal routing layer 1030. In certain embodiments, first metal routing layer 1020 is a metal routing layer with the power grid routes directly above transistor region 1010 and second metal routing layer 1030 is the next metal layer about the first metal routing layer vertically with respect to the substrate. It should be noted that various insulating (e.g., dielectric) or other connecting layers may be between transistor region 1010, first metal routing layer 1020, and second metal routing layer 1030.

In certain embodiments, transistor region 1010 includes tall cell 710 and short cell 720. Tall cell 710 may include, for example, two active regions 1012A, 1012B and short cell 720 may include two active regions 1014A, 1014B though other number of active regions may be possible. The size of active regions 1012A, 1012B and active regions 1014A, 1014B define the difference in sizes between tall cell 710 and short cell 720, respectively. As shown in FIG. 10, power grid routes 730 are placed at the boundaries of tall cell 710 and short cell 720, as shown by the dashed lines between transistor region 1010 and first metal routing layer 1020. In certain embodiments, as described herein, power grid routes are placed at centers of the boundaries.

With power grid routes 730 defined by the boundaries, a specified spacing between the power grid routes is defined in first metal routing layer 1020 with the spacing available being larger in association with tall cell 710 than short cell 720. Accordingly, the space associated with tall cell 710 may have a larger number of signal routes (e.g., six (6) signal routes 1022A-F placed at pitch 1024) while the space associated with short cell 720 may have a smaller number of signal routes (e.g., five (5) signal routes 1026A-E place at pitch 1028). It should be noted that the number of signal routes and the pitch of the signal routes may be varied independently or in combination depending on the desired operating properties of the design logic of column 1000. There may, however, be limitations on the number of signal routes or the pitch of the signal routes depending on the available space for signal routes.

Turning to second metal routing layer 1030, again the number of signal routes and the pitch of the signal routes may be varied based on the needs of the design logic of column 1000 and the space available. In various embodiments, the number of signal routes and the pitch of the signal routes in second metal routing layer 1030 do not have to match the number and pitch in first metal routing layer 1020. For example, as shown in FIG. 10, second metal layer routing layer 1030 may have seven (7) signal routes 1032A-H at pitch 1034 in the spacing associated with tall cell 710 whereas first metal routing layer 1020 only has six signal routes 1022A-F. Pitch 1034 and pitch 1024 may be similar or different depending on the design needs of column 1000.

Though the pitch of the signal routes in second metal routing layer 1030 do not have to match the number and pitch in first metal routing layer 1020, there may be some commonality between the values. For instance, second metal routing layer 1030 has five (5) signal routes 1036A-F at pitch 1038 where the number of signal routes matches the five signal routes 1026A-E in first metal routing layer 1020. Pitch 1038 for second metal routing layer 1030 is different than pitch 1028 for first metal routing layer 1020, as shown in FIG. 10.

As shown in FIGS. 8-10, with fixed width power grid routing, a cell may have either a short cell or a tall cell abutting the cell without any impact on the characterization of the cell with respect to power grid routing. Additionally, the power grid routing is placed at the center of a cell transition boundary and that center position may be maintained across a number of columns of blocks to allow the power grid route width to be constant across an entire partition (e.g., logic sub-block) within a logic block.

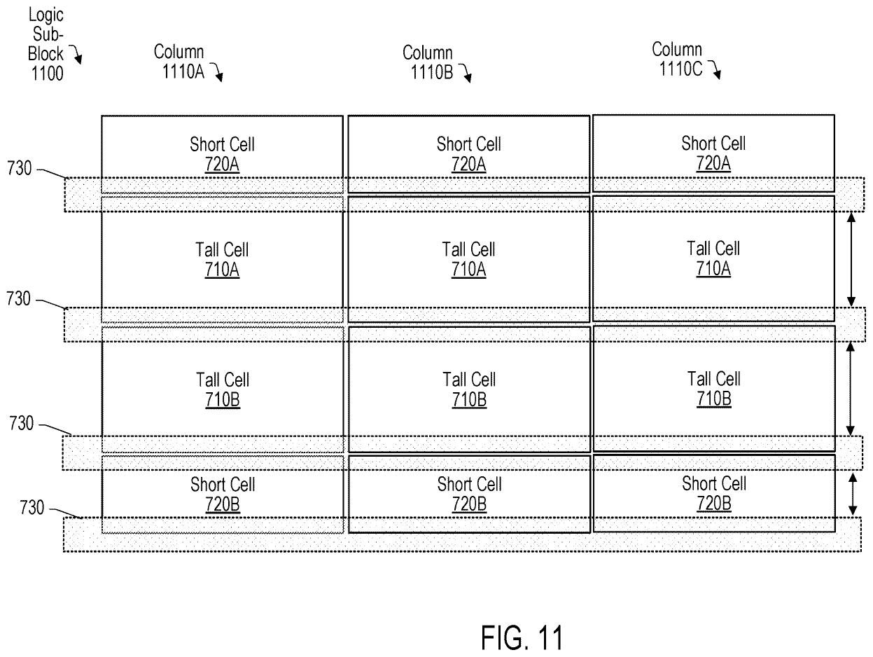

FIG. 11 depicts a top-view representation of a logic sub-block having three columns of cells with tall and short height cells and fixed width power grid routes across the columns of cells, according to some embodiments. In the illustrated embodiment, logic sub-block 1100 (e.g., a partition) includes three (3) columns 1110A, 1110B, 1110C. Columns 1110A, 1110B, 1110C have corresponding arrangements of short cells 720A-B and tall cells 710B based on fixed width power grid routes 730. With the consistent paths across columns 1110A, 1110B, 1110C, signal routes with specified numbers and/or pitches may be placed continuously above the columns in addition to the power grid routing.

Being able to design logic with different tall to short cell ratios across different partitions in a large logic block provides flexibility in the design of the large logic block whereas previously the large logic block had to include the same tall to short cell ratio across the entire block. This flexibility is allowed since each partition can different row structures without changing the characterization of the cells with the constant power grid route width.

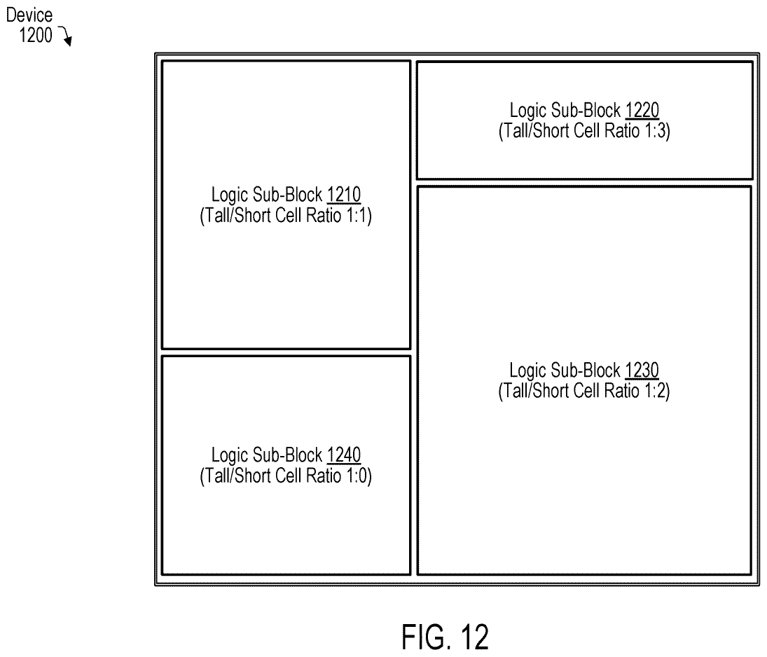

FIG. 12 depicts a plan view representation of a device having logic sub-blocks with different ratios of tall/short cells in the logic sub-blocks showing that the logic sub-blocks can have any ratio of tall/short cells regardless of location of logic sub-block in device, according to some embodiments. In the illustrated embodiment, device 1200 includes logic sub-blocks 1210, 1220, 1230, 1240. As shown in the illustrated embodiment, each of logic sub-blocks 1210, 1220, 1230, 1240 is capable of having a different ratio of tall to short cells. For instance, logic sub-block 1210 may have a tall to short cell ratio of 1:1, logic sub-block 1220 may have a tall to short cell ratio of 1:3, logic sub-block 1230 may have a tall to short cell ratio of 1:2, and logic sub-block 1240 may have a tall to short cell ratio of 1:0. Device 1200 may have any number of these partitions of logic sub-blocks and the tall to short cell ratios may be varied as desired. Additionally, further sub-partitions may also be created in some contemplated embodiments.

The various embodiments described with respect to FIGS. 5-12 provide row-based flexibility in designs of logic blocks. For instance, in the described embodiment, row structures may be adjusted for entire blocks (e.g., sub-blocks or partitions) with fixed width power grid routes to provide flexibility in the design of a logic block. The present disclosure further contemplates embodiments having column-based flexibility in logic blocks. As described below, column-based flexibility allows the cell heights of cells (e.g., flexible cells) to be varied to provide different operational performance and power optimization at specific locations in a device.

Turning back to FIGS. 1 and 2, device 100 and device 200, respectively, show cell height patterns that may be repeated in the cell width direction. Repeating the same patterns with the same cell widths across cells in the cell width direction, however, limits any flexibility in the placement of tall (large) cells (as shown in device 200). For instance, with the tall cells of device 200 repeated in the cell width direction, a higher percentage of the device becomes associated with the larger areas of the tall cells. More improvement in device optimization may be achieved by varying the placement of tall cells where they are needed rather than everywhere. For instance, tall cells may be placed at critical paths for higher speeds in a device architecture.

Specific placement of taller/shorter cells may be achieved with nanosheet transistors as nanosheet processing technologies allow jogs between active regions across different cell widths. The jogs are allowed due to the flexibility in patterning nanosheet fins with different widths (e.g., direct print or patterning instead of self-aligned multi-patterning). The jogs can be placed at dummy gate transitions between adjacent cells in the cell width direction. These jogs allow abutting cells in the cell width direction to have different cell heights.

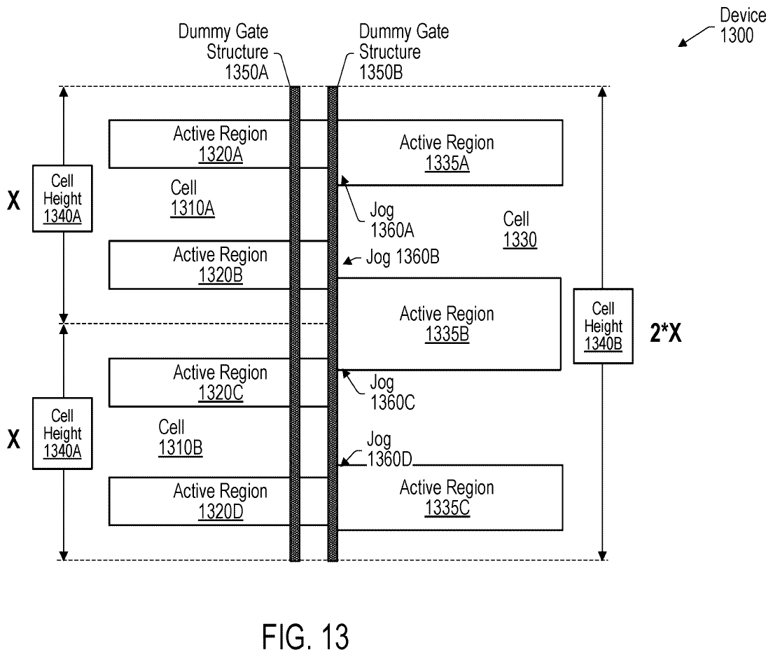

FIG. 13 depicts a top-view representation of a device having a column of two template cells of equal height abutting a column of one double height cell, according to some embodiments. In the illustrated embodiment, device 1300 includes cell 1310A and cell 1310B on a left side of the device in the cell width direction abutting cell 1330 on the right side of the device in the cell width direction. Dummy gate structures 1350A, 1350B are placed at the transition between cells 1310A/1310B and cell 1330 to allow changes (e.g., jogs 1360) in the active regions' locations and widths. Cell 1310A and cell 1310B have cell height 1340A while cell 1330 has cell height 1340B.

In the illustrated embodiment, cell 1310A has active regions 1320A-B and cell 1310B has active regions 1320C-D. Active regions 1320A-D have uniform widths in the cell height direction as defined by cell height 1340A. In device 1300, cell height 1340B is determined from cell height 1340A based on a fixed ratio (e.g., cell height 1340A is X and cell height 1340B is 2× with both constrained by integer fundamentals). The fixed ratio may be necessary to accommodate connections to fixed grid power routing above/below device 1300 and maintain cell height repeatability across the power routing grid. Jogs 1360A-D and widths of active regions 1335A-C in cell 1330 are then determined based on the fixed ratio. With these predetermined jogs and widths, a taller active region is provided by merging active region 1320B and active region 1320C into a single active region, active region 1335B, with jogs 1360B and 1360C. Active regions 1335A and 1335C may also have slightly wider widths than corresponding active regions 1320A and 1320D by using jog 1360A and jog 1360D, respectively.

While device 1300 allows for the placement of taller active regions where they are more likely to be needed (e.g., in critical paths), the fixed ratio of the jogs and cell heights places limitations on the device. For instance, in cell 1330, active regions 1335A-C may have limited width choices, which can put a limit on power and performance optimization.

The present disclosure illustrates various embodiments of integrated circuit cells with flexible hybrid cell structures that overcome the limitations of uniform height standard cells and hybrid standard cells with fixed ratios. The flexible hybrid cell structures described herein include cell structures where heights of integrated circuit cells (e.g., active region widths) are flexibly varied to provide various advantageous properties including, but not limited to, better performance and power optimization based on a specific device's needs. As disclosed herein, integrated circuit cell heights may be varied on a column-by-column basis to provide the various flexible hybrid cell structures depicted herein.

Certain embodiments described herein have three broad elements: 1) a standard cell structure of nanosheet active regions with widths in a column direction and lengths in a row direction; 2) a first column of template active transistor cells where a number of rows of template active transistor cells in a first column is at least two and a total height of the first column is a sum of the cell heights for the template active transistor cells in the first column, and 3) a second column of flexible active transistor cells where a number of rows of flexible active transistor cells in a second column is at least two and at most equal to the number of rows of template active transistor cells in the first column. In some embodiments, the cell heights of the template active transistor cells in the first column are substantially the same. In various embodiments, at least one flexible active transistor cell in the second column has a cell height different from a cell height of at least one other flexible active transistor cell in the second column. A total height of the second column may be a sum of the cell heights for the flexible active transistor cells in the second column with the total height of the second column being equal to the total height of the first column.

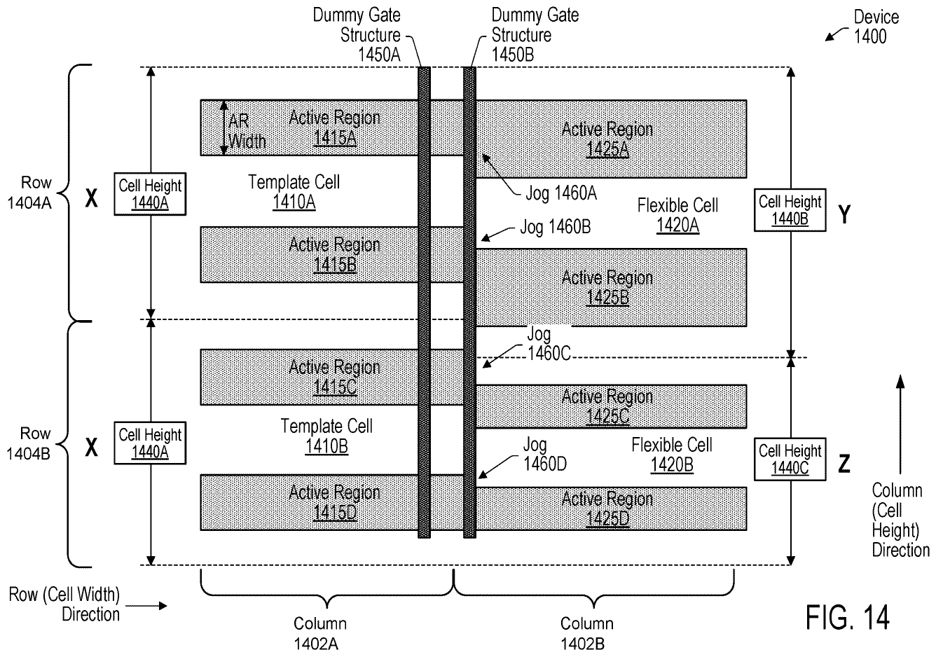

FIG. 14 depicts a top-view representation of a device having a column of two template cells of equal height abutting a column of two flexible cells with different heights, according to some embodiments. In the illustrated embodiment, device 1400 includes template cells 1410A, 1410B in column 1402A on a left side of the device in the cell width (row) direction and flexible cells 1420A, 1420B in column 1402B on a right side of the device in the cell width direction. Template cells 1410A, 1410B may be cells with active regions 1415A-D that have uniform widths across the active regions (e.g., the widths of the active regions in the cell height (column) direction are substantially the same). Thus, template cell 1410A and template cell 1410B both have cell height 1440A (cell height=X) with template cell 1410A in row 1404A and template cell 1410B in row 1404B.

In various embodiments, as shown in FIG. 14, dummy gate structures 1450A and 1450B are placed in the transition between column 1402A and column 1402B. As discussed above, with dummy gate structures 1450A-B in place, jogs 1460A-D may be implemented between column 1402 and column 1402B to provide changes in the position and/or size of the active regions between the columns. In certain embodiments, jogs 1460A-D allow changes in position and/or size of the active regions within certain constraints associated with power grid routing above or below the device. For instance, the power grid routing is continuous across the columns in the cell width (row) direction and shared between abutting rows in the cell height (column) direction regardless of what widths the abutting pairs of cells in the rows have. Signal routing above/below the device is also continuous across the columns in the cell width (row) direction.

The present disclosure, however, recognizes that additional flexibility in the design of cell heights is possible while maintaining connections to the power grid routing and signal routing under the constraints of the power grid routing and the signal routing across adjacent (abutting) columns of template cells (e.g., standard height cells) and flexible cells (e.g., flexible height cells). The additional flexibility in the flexible cell heights adjacent template cells correspondingly provides more flexibility in the sizes of the active regions within the device and allows designs of transistors to be more specifically tailored to needs of the device. For example, taller power cells with higher speeds may be placed at specific locations for critical tasks requiring higher frequency.

As shown in FIG. 14, column 1402B includes flexible cell 1420A with cell height 1440B and flexible cell 1420B with cell height 1440C. In various embodiments, the combination of cell height 1440B plus cell height 1440C is substantially the same as twice cell height 1440A (the combined height of template cell 1410A and template cell 1410B). In certain embodiments, flexible cell 1420A and flexible cell 1420B have different cell heights (e.g., cell height 1440B is different from cell height 1440C). Using different cell heights provides a combination of cells with one being taller (with wider active regions) and one shorter (with narrower active regions). This combination of cells may provide better performance through the implementation of the taller cell while providing power optimization through the shorter cell. Having flexible cells of different heights provides more granularity and freedom in the design of device 1400 and decouples the design of the device from the integer fundamentals (e.g., fixed ratio) of previous designs (such as device 1300, shown in FIG. 13). In one example embodiment, cell height 1440B (Y) is 1.4 times cell height 1440C (Z) and the combination is also equal to twice cell height 1440A (2X).

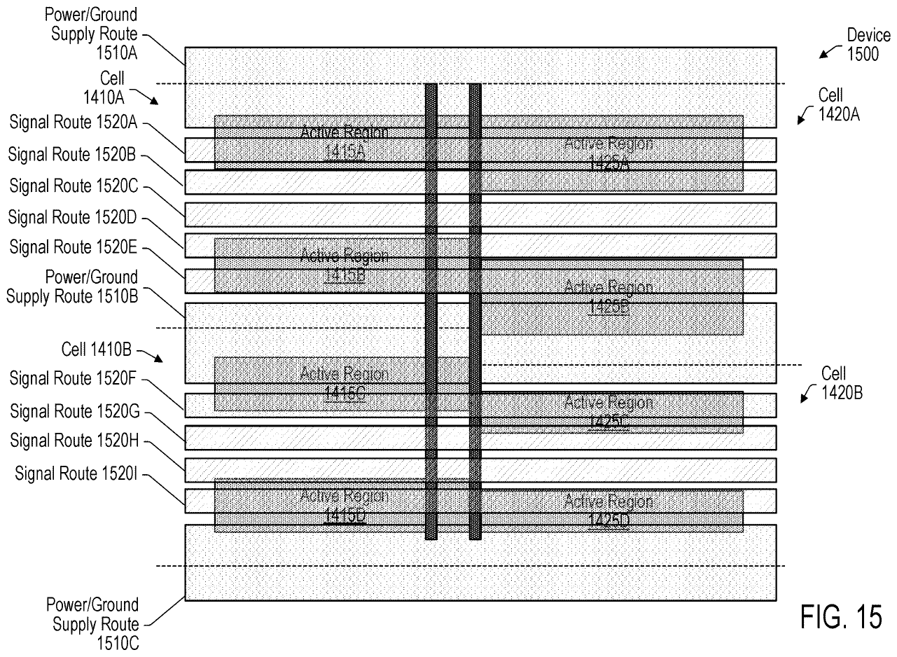

Having the combined heights of flexible cells 1420A and 1420B in column 1402B the same as the combined heights of template cells 1410 and 1410B in column 1402A maintains area availability for the connections to the corresponding power grid and signal routing above (or below) the device. FIG. 15 depicts a top-view representation of the device of FIG. 14 with power and signal routing positioned vertically above the device (relative to the substrate), according to some embodiments. In the illustrated embodiment, device 1500 includes power/ground supply routes 1510A-C and signal routes 1520A-I routed above template cells 1410A, 1410B and flexible cells 1420A, 1420B. In certain embodiments, power/ground supply routes 1510A-C and signal routes 1520A-I are continuous above template cells 1410A, 1410B and flexible cells 1420A, 1420B. Power/ground supply routes 1510A-C and signal routes 1520A-I may also continuously extend to neighboring cells in the cell width (row) direction.

In various embodiments, as shown in FIG. 15, template cells 1410A, 1410B and flexible cells 1420A, 1420B are laid out and have sizes that place power/ground supply routes 1510A-C and signal routes 1520A-I at positions accessible by the cells and sharable among the cells. For example, power/ground supply route 1510B is accessible by each of template cells 1410A, 1410B and flexible cells 1420A, 1420B as well as being sharable between the cells. Accordingly, power/ground supply route 1510B may provide power/ground supply that is shared between template cells 1410A, 1410B and flexible cells 1420A, 1420B. In some embodiments, the heights of flexible cells 1420A, 1420B may be determined, at least in part, to ensure access to any of power/ground supply routes 1510A-C and signal routes 1520A-I.

In certain embodiments, the integrity of the power/ground supply and signal routing for device 1500 is maintained across the template cells and flexible cells. For instance, template cell 1410A has alignment in the cell width (row) direction with flexible cell 1420A so that each cell has the same number of signal routes 1520A-E. Similarly, template cell 1410B has alignment in the cell width (row) direction with flexible cell 1420B to have the same signal routes 1520F-I. Due to the difference in sizes between flexible cell 1420A and flexible cell 1420B, the flexible cells may have different numbers of signal routes though it is possible in some instances for them to have the same number of signal routes.

As shown in FIGS. 14 and 15, a column of flexible cells 1420 may be abutted a column of template cells 1410. Flexible cells 1420, as described herein, may be placed at specified locations in a device layout to provide higher operating performance at critical path locations. In many embodiments, flexible cells 1420 are placed in a column between columns of template cells 1410 to position the flexible cells in the specified location.

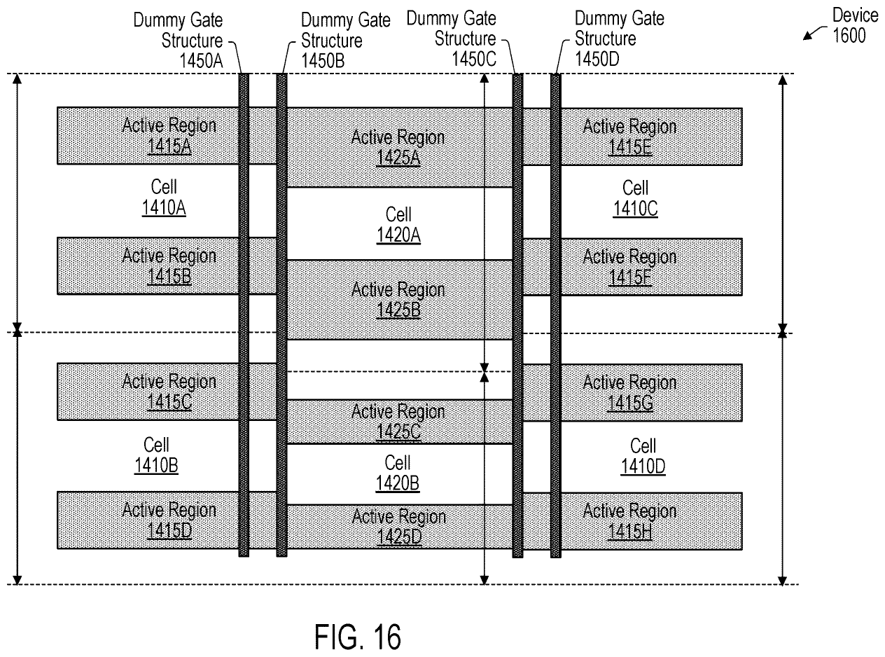

FIG. 16 depicts a top-view representation of a device having a column of two flexible cells with different heights positioned between (and abutting) two columns of two template cells of equal heights, according to some embodiments. In the illustrated embodiment, device 1600 includes a column of flexible cells 1420A, 1420B with active regions 1425A-D positioned and abutted between two columns of template cells 1410A-D with active regions 1415A-H. As described previously, dummy gate structures 1450A-D are placed at the boundaries between the columns of template cells and column of flexible cells to allow for jogs in the dimensions of the active regions.

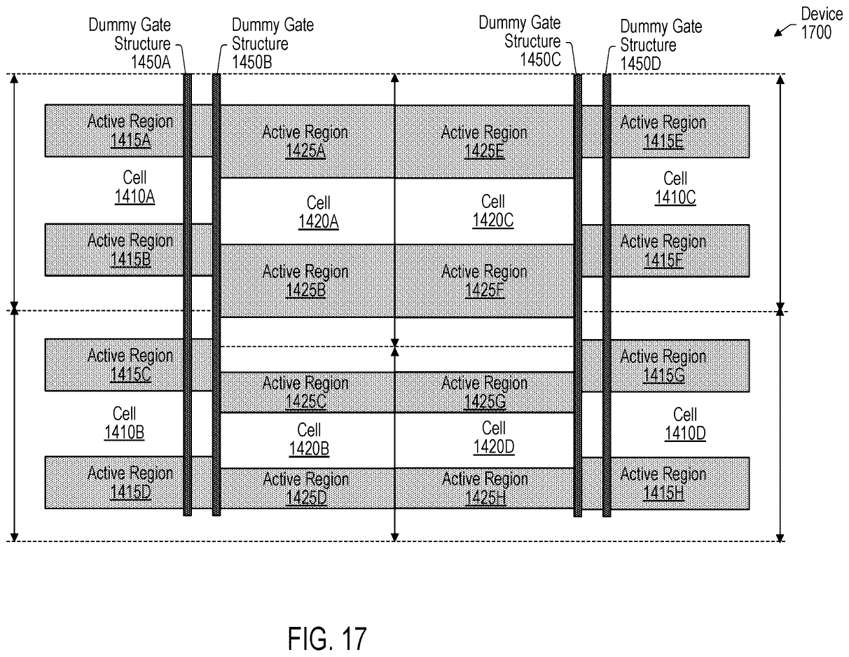

In some embodiments, multiple columns of flexible cells may be placed adjacent between columns of template cells. FIG. 17 depicts a top-view representation of a device having two columns of two flexible cells with different heights positioned between (and abutting) two columns of two template cells of equal height, according to some embodiments. In the illustrated embodiment, device 1700 includes two columns of flexible cells 1420A-D with active regions 1425A-H placed between dummy gate structures 1450A-D and template cells 1410A-D with active regions 1415A-H. The adjacent columns of flexible cells may provide further improvement in operational performance (e.g., frequency) at a specified location. Other numbers of adjacent columns of flexible cells may also be contemplated.

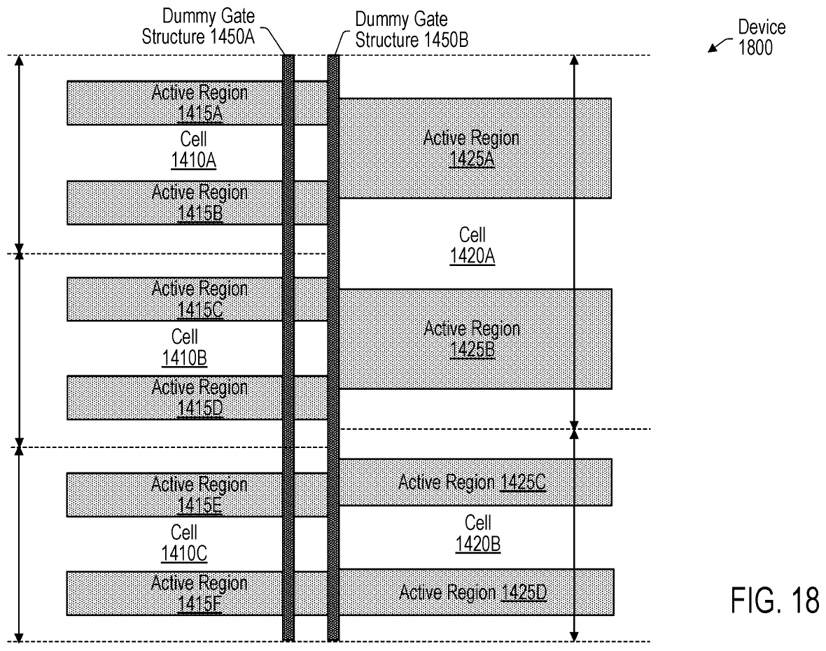

Further embodiments may be contemplated with different number of template cells in the cell height (column) direction. For instance, a template of three or more template cells may be used to set a number of flexible cells adjacent the template cells. In such embodiments, generally a set of flexible cells adjacent a set of template cells needs to have the same number of cells or the number of flexible cells can be less than the template cells as long as the combined height of the set of flexible cells is equal to the combined height of the template cells. For example, a set of two (2) flexible cells may have the same combined height as a set of three (3) template cells. This constraint is due to the availability of power/ground supply routes that are needed for the flexible cells cannot exceed those for the template cells. FIGS. 18-20 depict examples of additional embodiments of combinations of template cells and flexible cells that may be possible according to these constraints.

FIG. 18 depicts a top-view representation of a device having a column of three template cells of equal heights abutting a column of two flexible cells with different heights, according to some embodiments. In the illustrated embodiment, device 1800 includes three rows of template cells 1410A-C with active regions 1415A-F. Dummy gate structures 1450A-B are placed adjacent to template cells 1410A-C and allow jogs to form active regions 1425A-D in flexible cells 1420A-B. As shown in FIG. 18, the combined height of flexible cell 1420A and flexible cell 1420B is the same as the combined height of template cells 1410A-C. This allows the power/supply routing and signal routing to remain continuous across the template cells and flexible cells and with access for the underlying cells. Having two flexible cells adjacent three template cells allows a larger flexible cell (e.g., flexible cell 1420A) to be implemented and provide further improved performance at the location of the flexible cells in device 1800.

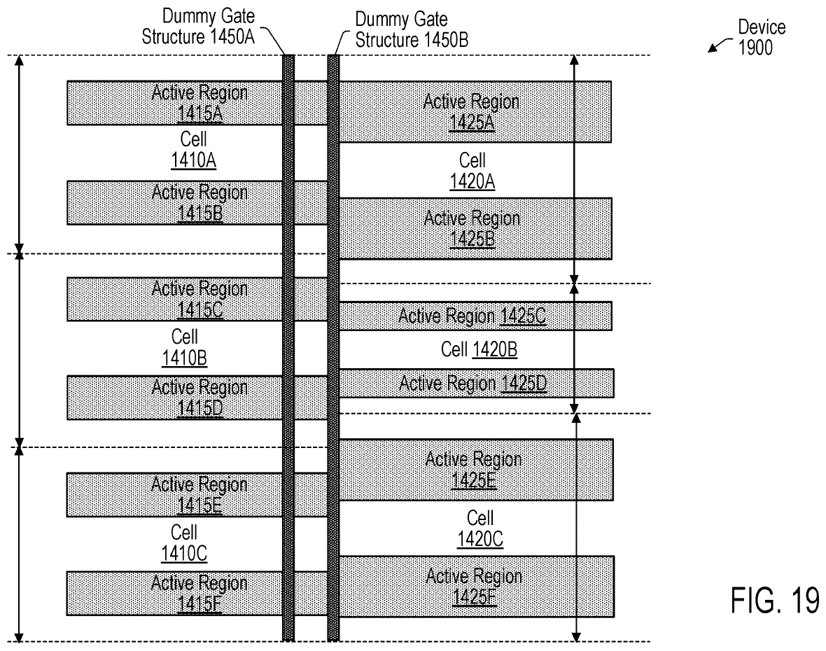

In some embodiments, having a number of template cells greater than two allows further variation in the heights of the flexible cells. FIG. 19 depicts a top-view representation of a device having a column of three template cells of equal heights abutting a column of three flexible cells with two flexible cells having equal heights and the third cell having a different height, according to some embodiments. In the illustrated embodiment, device 1900 includes three rows of template cells 1410A-C with active regions 1415A-F. Dummy gate structures 1450A-B are placed adjacent to template cells 1410A-C and allow jogs to form active regions 1425A-F in three flexible cells 1420A-C. As shown in FIG. 19, flexible cell 1420A and flexible cell 1420C have the same height while flexible cell 1420B has a different height. The heights of flexible cells 1420A-C maintain a combined height that is equal to the combined height of template cells 1410A-C. Being able to have a single flexible cell with a different height allows the design of device 1900 to be tailored to a specific performance characteristic.

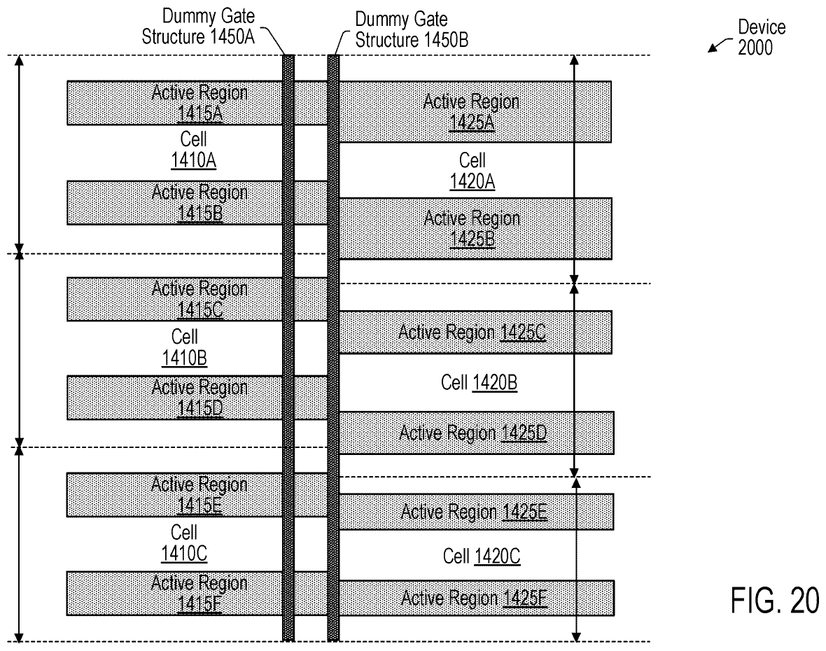

In some embodiments, flexible cells may have individually selected heights. FIG. 20 depicts a top-view representation of a device having a column of three template cells of equal heights abutting a column of three flexible cells with different heights, according to some embodiments. In the illustrated embodiment, device 2000 includes three rows of template cells 1410A-C with active regions 1415A-F. Dummy gate structures 1450A-B are placed adjacent to template cells 1410A-C and allow jogs to form active regions 1425A-F in three flexible cells 1420A-C. As shown in FIG. 20, flexible cells 1420A-C each have different heights. The heights of flexible cells 1420A-C may be varied in any combination to achieve a combined height that is equal to the combined height of template cells 1410A-C. Being able to individually vary the heights of flexible cells 1420A-C allows the design of device 2000 to be tailored to a variety of different performance characteristics.

FIGS. 14-20 describe various embodiments where columns of cells with flexible cell heights (e.g., flexible cells 1420) are placed adjacent template cells with standard cell heights. The standard cell heights are primarily determined based on the spacing of the routing above (or below) the template cells for power/ground supply and signals. Implementing the flexible cells adjacent template cells allows placement of cells tailored to provide certain operational performance and/or power optimization properties at specified locations in a device while maintaining the integrity of the power/ground supply and signal routing for the device.

In various embodiments, as described herein, a set (e.g., one or more columns) of flexible cells with a horizontal length in the row (cell width) direction that is an integer number of the gate pitch may be inserted between columns of standard (template) cells where the top and bottom of the set of flexible cells in the column (cell height) direction align with the top and bottom of the columns of template cells. The number of flexible cells in a column between the top and bottom may be equal to or less than the number of template cells between the top and bottom. Dummy gate transitions (with dummy active regions) may be placed between the template cells and flexible cells to provide transitions and jogs in position between their active regions. Heights of the flexible cells may be varied depending on the constraints of the associated power/ground supply and signal routing and dimensions of the adjacent template cells. The described embodiments allow larger, flexible cells to be placed at specified locations for pushing operational performance (e.g., operation frequency) above what is possible with standard template cells while the smaller flexible cells may be used for optimizing power consumption beyond what is possible with template cells.

The embodiments disclosed in FIGS. 14-20 provide column-based flexibility in the design of standard cell-based device structures where the cell heights of cells (e.g., flexible cells) are varied to provide different operational performance and power optimization at specific locations in the device. The column-based flexibility provides advantages over devices with uniform dimensions (e.g., uniform active region widths in uniform standard cell libraries).

While the embodiments disclosed herein generally describe metal routing layers above transistor cells and substrates (e.g., in a topside or frontside of an integrated circuit device), it should be understood that the various metal routing layers described may also be placed below the substrates (e.g., in a backside of the integrated circuit device). Accordingly, various embodiments of backside metal layer routing may be contemplated based on the disclosed embodiments of topside metal layer routing. For instance, where it is described that metal routing layers or power grid routes are positioned above the cells or vertically above relative to the substrate with respect to topside metal layer routing, embodiments may also be considered where the metal routing layers or power grid routes are “vertically displaced from the substrate” with the metal routing layers or power grid routes being either above or below the substrate depending on whether topside or backside routing is implemented. Correspondingly, the metal routing layers or power grid routes may be considered to be “vertically displaced from the transistor cells [and the substrate]” depending on whether topside or backside routing is implemented. Further, individual metal routing layers or power grid routes in different layers may be considered to be “vertically displaced” depending on whether a layer or route is above or below another layer or route.

### Example Computer System

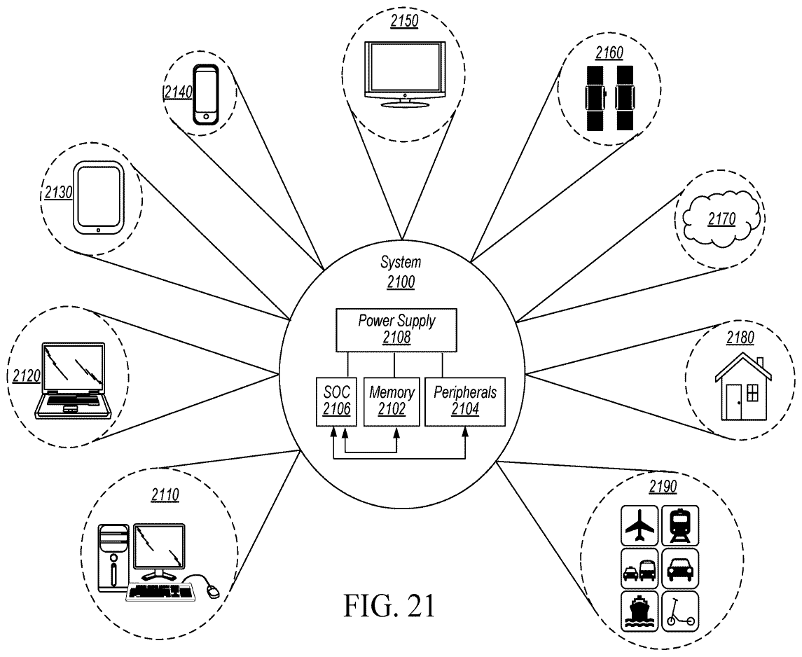

Turning next to FIG. 21, a block diagram of one embodiment of a system 2100 is shown that may incorporate and/or otherwise utilize the methods and mechanisms described herein. In the illustrated embodiment, the system 2100 includes at least one instance of a system on chip (SoC) 2106 which may include multiple types of processing units, such as a central processing unit (CPU), a graphics processing unit (GPU), or otherwise, a communication fabric, and interfaces to memories and input/output devices. In some embodiments, one or more processors in SoC 2106 includes multiple execution lanes and an instruction issue queue. In various embodiments, SoC 2106 is coupled to external memory 2102, peripherals 2104, and power supply 2108.

A power supply 2108 is also provided which supplies the supply voltages to SoC 2106 as well as one or more supply voltages to the memory 2102 and/or the peripherals 2104. In various embodiments, power supply 2108 represents a battery (e.g., a rechargeable battery in a smart phone, laptop or tablet computer, or other device). In some embodiments, more than one instance of SoC 2106 is included (and more than one external memory 2102 is included as well).

The memory 2102 is any type of memory, such as dynamic random access memory (DRAM), synchronous DRAM (SDRAM), double data rate (DDR, DDR2, DDR3, etc.) SDRAM (including mobile versions of the SDRAMs such as mDDR3, etc., and/or low power versions of the SDRAMs such as LPDDR2, etc.), RAMBUS DRAM (RDRAM), static RAM (SRAM), etc. One or more memory devices are coupled onto a circuit board to form memory modules such as single inline memory modules (SIMMs), dual inline memory modules (DIMMs), etc. Alternatively, the devices are mounted with a SoC or an integrated circuit in a chip-on-chip configuration, a package-on-package configuration, or a multi-chip module configuration.

The peripherals 2104 include any desired circuitry, depending on the type of system 2100. For example, in one embodiment, peripherals 2104 includes devices for various types of wireless communication, such as Wi-Fi, Bluetooth, cellular, global positioning system, etc. In some embodiments, the peripherals 2104 also include additional storage, including RAM storage, solid state storage, or disk storage. The peripherals 2104 include user interface devices such as a display screen, including touch display screens or multitouch display screens, keyboard or other input devices, microphones, speakers, etc.

As illustrated, system 2100 is shown to have application in a wide range of areas. For example, system 2100 may be utilized as part of the chips, circuitry, components, etc., of a desktop computer 2110, laptop computer 2120, tablet computer 2130, cellular or mobile phone 2140, or television 2150 (or set-top box coupled to a television). Also illustrated is a smartwatch and health monitoring device 2160. In some embodiments, smartwatch may include a variety of general-purpose computing related functions. For example, smartwatch may provide access to email, cellphone service, a user calendar, and so on. In various embodiments, a health monitoring device may be a dedicated medical device or otherwise include dedicated health related functionality. For example, a health monitoring device may monitor a user's vital signs, track proximity of a user to other users for the purpose of epidemiological social distancing, contact tracing, provide communication to an emergency service in the event of a health crisis, and so on. In various embodiments, the above-mentioned smartwatch may or may not include some or any health monitoring related functions. Other wearable devices are contemplated as well, such as devices worn around the neck, devices that are implantable in the human body, glasses designed to provide an augmented and/or virtual reality experience, and so on.

System 2100 may further be used as part of a cloud-based service(s) 2170. For example, the previously mentioned devices, and/or other devices, may access computing resources in the cloud (i.e., remotely located hardware and/or software resources). Still further, system 2100 may be utilized in one or more devices of a home 2180 other than those previously mentioned. For example, appliances within the home may monitor and detect conditions that warrant attention. For example, various devices within the home (e.g., a refrigerator, a cooling system, etc.) may monitor the status of the device and provide an alert to the homeowner (or, for example, a repair facility) should a particular event be detected. Alternatively, a thermostat may monitor the temperature in the home and may automate adjustments to a heating/cooling system based on a history of responses to various conditions by the homeowner. Also illustrated in FIG. 21 is the application of system 2100 to various modes of transportation 2190. For example, system 2100 may be used in the control and/or entertainment systems of aircraft, trains, buses, cars for hire, private automobiles, waterborne vessels from private boats to cruise liners, scooters (for rent or owned), and so on. In various cases, system 2100 may be used to provide automated guidance (e.g., self-driving vehicles), general systems control, and otherwise. These any many other embodiments are possible and are contemplated. It is noted that the devices and applications illustrated in FIG. 21 are illustrative only and are not intended to be limiting. Other devices are possible and are contemplated.

The present disclosure includes references to “an “embodiment” or groups of “embodiments” (e.g., “some embodiments” or “various embodiments”). Embodiments are different implementations or instances of the disclosed concepts. References to “an embodiment,” “one embodiment,” “a particular embodiment,” and the like do not necessarily refer to the same embodiment. A large number of possible embodiments are contemplated, including those specifically disclosed, as well as modifications or alternatives that fall within the spirit or scope of the disclosure.

This disclosure may discuss potential advantages that may arise from the disclosed embodiments. Not all implementations of these embodiments will necessarily manifest any or all of the potential advantages. Whether an advantage is realized for a particular implementation depends on many factors, some of which are outside the scope of this disclosure. In fact, there are a number of reasons why an implementation that falls within the scope of the claims might not exhibit some or all of any disclosed advantages. For example, a particular implementation might include other circuitry outside the scope of the disclosure that, in conjunction with one of the disclosed embodiments, negates or diminishes one or more the disclosed advantages. Furthermore, suboptimal design execution of a particular implementation (e.g., implementation techniques or tools) could also negate or diminish disclosed advantages. Even assuming a skilled implementation, realization of advantages may still depend upon other factors such as the environmental circumstances in which the implementation is deployed. For example, inputs supplied to a particular implementation may prevent one or more problems addressed in this disclosure from arising on a particular occasion, with the result that the benefit of its solution may not be realized. Given the existence of possible factors external to this disclosure, it is expressly intended that any potential advantages described herein are not to be construed as claim limitations that must be met to demonstrate infringement. Rather, identification of such potential advantages is intended to illustrate the type(s) of improvement available to designers having the benefit of this disclosure. That such advantages are described permissively (e.g., stating that a particular advantage “may arise”) is not intended to convey doubt about whether such advantages can in fact be realized, but rather to recognize the technical reality that realization of such advantages often depends on additional factors.

Unless stated otherwise, embodiments are non-limiting. That is, the disclosed embodiments are not intended to limit the scope of claims that are drafted based on this disclosure, even where only a single example is described with respect to a particular feature. The disclosed embodiments are intended to be illustrative rather than restrictive, absent any statements in the disclosure to the contrary. The application is thus intended to permit claims covering disclosed embodiments, as well as such alternatives, modifications, and equivalents that would be apparent to a person skilled in the art having the benefit of this disclosure.

For example, features in this application may be combined in any suitable manner. Accordingly, new claims may be formulated during prosecution of this application (or an application claiming priority thereto) to any such combination of features. In particular, with reference to the appended claims, features from dependent claims may be combined with those of other dependent claims where appropriate, including claims that depend from other independent claims. Similarly, features from respective independent claims may be combined where appropriate.

Accordingly, while the appended dependent claims may be drafted such that each depends on a single other claim, additional dependencies are also contemplated. Any combinations of features in the dependent that are consistent with this disclosure are contemplated and may be claimed in this or another application. In short, combinations are not limited to those specifically enumerated in the appended claims.

Where appropriate, it is also contemplated that claims drafted in one format or statutory type (e.g., apparatus) are intended to support corresponding claims of another format or statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to a singular form of an item (i.e., a noun or noun phrase preceded by,” “an,” or “the”) are, unless context clearly dictates otherwise, intended to mean “one or more.” Reference to “an item” in a claim thus does not, without accompanying context, preclude additional instances of the item. A “plurality” of items refers to a set of two or more of the items.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” and thus covers 1) x but not y, 2) y but not x, and 3) both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of elements. This phrase is not to be interpreted to require that there is at least one instance of w, at least one instance of x, at least one instance of y, and at least one instance of z.

Various “labels” may precede nouns or noun phrases in this disclosure. Unless context provides otherwise, different labels used for a feature (e.g., “first circuit,” “second circuit,” “particular circuit,” “given circuit,” etc.) refer to different instances of the feature. Additionally, the labels “first,” “second,” and “third” when applied to a feature do not imply any type of ordering (e.g., spatial, temporal, logical, etc.), unless stated otherwise.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrases “in response to” and “responsive to” describe one or more factors that trigger an effect. This phrase does not foreclose the possibility that additional factors may affect or otherwise trigger the effect, either jointly with the specified factors or independent from the specified factors. That is, an effect may be solely in response to those factors, or may be in response to the specified factors as well as other, unspecified factors. Consider the phrase “perform A in response to B.” This phrase specifies that B is a factor that triggers the performance of A, or that triggers a particular result for A. This phrase does not foreclose that performing A may also be in response to some other factor, such as C. This phrase also does not foreclose that performing A may be jointly in response to B and C. This phrase is also intended to cover an embodiment in which A is performed solely in response to B. As used herein, the phrase “responsive to” is synonymous with the phrase “responsive at least in part to.” Similarly, the phrase “in response to” is synonymous with the phrase “at least in part in response to.”

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as being “configured to” perform some task refers to something physical, such as a device, circuit, a system having a processor unit and a memory storing program instructions executable to implement the task, etc. This phrase is not used herein to refer to something intangible.

In some cases, various units/circuits/components may be described herein as performing a set of task or operations. It is understood that those entities are “configured to” perform those tasks/operations, even if not specifically noted.

The term “configured to” is not intended to mean “configurable to.” An unprogrammed FPGA, for example, would not be considered to be “configured to” perform a particular function. This unprogrammed FPGA may be “configurable to” perform that function, however. After appropriate programming, the FPGA may then be said to be “configured to” perform the particular function.

For purposes of United States patent applications based on this disclosure, reciting in a claim that a structure is “configured to” perform one or more tasks is expressly intended not to invoke 35 U.S.C. § 112(f) for that claim element. Should Applicant wish to invoke Section 112(f) during prosecution of a United States patent application based on this disclosure, it will recite claim elements using the “means for” [performing a function] construct.

Different “circuits” may be described in this disclosure. These circuits or “circuitry” constitute hardware that includes various types of circuit elements, such as combinatorial logic, clocked storage devices (e.g., flip-flops, registers, latches, etc.), finite state machines, memory (e.g., random-access memory, embedded dynamic random-access memory), programmable logic arrays, and so on. Circuitry may be custom designed, or taken from standard libraries. In various implementations, circuitry can, as appropriate, include digital components, analog components, or a combination of both. Certain types of circuits may be commonly referred to as “units” (e.g., a decode unit, an arithmetic logic unit (ALU), functional unit, memory management unit (MMU), etc.). Such units also refer to circuits or circuitry.

The disclosed circuits/units/components and other elements illustrated in the drawings and described herein thus include hardware elements such as those described in the preceding paragraph. In many instances, the internal arrangement of hardware elements within a particular circuit may be specified by describing the function of that circuit. For example, a particular “decode unit” may be described as performing the function of “processing an opcode of an instruction and routing that instruction to one or more of a plurality of functional units,” which means that the decode unit is “configured to” perform this function. This specification of function is sufficient, to those skilled in the computer arts, to connote a set of possible structures for the circuit.

In various embodiments, as discussed in the preceding paragraph, circuits, units, and other elements defined by the functions or operations that they are configured to implement. The arrangement and such circuits/units/components with respect to each other and the manner in which they interact form a microarchitectural definition of the hardware that is ultimately manufactured in an integrated circuit or programmed into an FPGA to form a physical implementation of the microarchitectural definition. Thus, the microarchitectural definition is recognized by those of skill in the art as structure from which many physical implementations may be derived, all of which fall into the broader structure described by the microarchitectural definition. That is, a skilled artisan presented with the microarchitectural definition supplied in accordance with this disclosure may, without undue experimentation and with the application of ordinary skill, implement the structure by coding the description of the circuits/units/components in a hardware description language (HDL) such as Verilog or VHDL. The HDL description is often expressed in a fashion that may appear to be functional. But to those of skill in the art in this field, this HDL description is the manner that is used transform the structure of a circuit, unit, or component to the next level of implementational detail. Such an HDL description may take the form of behavioral code (which is typically not synthesizable), register transfer language (RTL) code (which, in contrast to behavioral code, is typically synthesizable), or structural code (e.g., a netlist specifying logic gates and their connectivity). The HDL description may subsequently be synthesized against a library of cells designed for a given integrated circuit fabrication technology, and may be modified for timing, power, and other reasons to result in a final design database that is transmitted to a foundry to generate masks and ultimately produce the integrated circuit. Some hardware circuits or portions thereof may also be custom-designed in a schematic editor and captured into the integrated circuit design along with synthesized circuitry. The integrated circuits may include transistors and other circuit elements (e.g., passive elements such as capacitors, resistors, inductors, etc.) and interconnect between the transistors and circuit elements. Some embodiments may implement multiple integrated circuits coupled together to implement the hardware circuits, and/or discrete elements may be used in some embodiments. Alternatively, the HDL design may be synthesized to a programmable logic array such as a field programmable gate array (FPGA) and may be implemented in the FPGA. This decoupling between the design of a group of circuits and the subsequent low-level implementation of these circuits commonly results in the scenario in which the circuit or logic designer never specifies a particular set of structures for the low-level implementation beyond a description of what the circuit is configured to do, as this process is performed at a different stage of the circuit implementation process.

The fact that many different low-level combinations of circuit elements may be used to implement the same specification of a circuit results in a large number of equivalent structures for that circuit. As noted, these low-level circuit implementations may vary according to changes in the fabrication technology, the foundry selected to manufacture the integrated circuit, the library of cells provided for a particular project, etc. In many cases, the choices made by different design tools or methodologies to produce these different implementations may be arbitrary.

Moreover, it is common for a single implementation of a particular functional specification of a circuit to include, for a given embodiment, a large number of devices (e.g., millions of transistors). Accordingly, the sheer volume of this information makes it impractical to provide a full recitation of the low-level structure used to implement a single embodiment, let alone the vast array of equivalent possible implementations. For this reason, the present disclosure describes structure of circuits using the functional shorthand commonly employed in the industry.

What is claimed is:

1. A semiconductor apparatus, comprising:
a substrate;
a plurality of active transistor cells formed on the substrate, the active transistor cells being arranged in columns and rows in a planar dimension above the substrate, wherein the active transistor cells have cell heights in a column direction of the planar dimension and cell widths in a row direction of the planar dimension, the row direction being orthogonal to the column direction, wherein the active transistor cells include nanosheet active regions with widths in the column direction and lengths in the row direction, wherein a set of active transistor cells in a column by row arrangement includes:
a first column of template active transistor cells, wherein a number of rows of template active transistor cells in the first column is at least two, and wherein a total height of the first column is a sum of the cell heights for the template active transistor cells in the first column, the cell heights of the template active transistor cells in the first column being substantially the same; and
a second column of flexible active transistor cells, wherein a number of rows of flexible active transistor cells in the second column is at least two and at most equal to the number of rows of template active transistor cells in the first column, at least one flexible active transistor cell in the second column having a cell height different from a cell height of at least one other flexible active transistor cell in the second column, and wherein a total height of the second column is a sum of the cell heights for the flexible active transistor cells in the second column, the total height of the second column being equal to the total height of the first column.

2. The apparatus of claim 1, wherein the at least one flexible active transistor cell in the second column has a cell height that is different from a cell height of at least one template active transistor cell in the first column.

3. The apparatus of claim 1, wherein the first column includes two rows of template active transistor cells and the second column includes two rows of flexible active transistor cells.

4. The apparatus of claim 1, wherein the first column includes three rows of template active transistor cells and the second column includes two rows of flexible active transistor cells.

5. The apparatus of claim 1, wherein the first column includes three rows of template active transistor cells and the second column includes three rows of flexible active transistor cells.

6. The apparatus of claim 1, wherein the first column has a constant cell width in the row direction, and wherein the second column has a constant cell width in the row direction.

7. The apparatus of claim 1, wherein the template active transistor cells have nanosheet active regions with widths and lengths that are the same.

8. The apparatus of claim 1, wherein the flexible active transistor cells have nanosheet active regions with lengths that are the same and with widths that vary based on the cell heights for the flexible active transistor.

9. The apparatus of claim 1, wherein entireties of the template active transistor cells abuts each other in the row direction, and wherein entireties of the flexible active transistor cells abuts each other in the row direction.

10. The apparatus of claim 1, wherein a portion of at least one of the template active transistor cells abuts a portion of at least one of the flexible active transistor cells in the column direction.

11. The apparatus of claim 1, further comprising at least one dummy gate structure oriented in the column direction along a border between the first column and the second column.

12. The apparatus of claim 11, wherein a border between at least two rows of the template active transistor cells in the first column jogs at the at least one dummy gate structure to a border between at least two rows of the flexible active transistor cells in the second column.

13. A semiconductor apparatus, comprising:
a substrate;
a plurality of active transistor cells formed on the substrate, the active transistor cells being arranged in columns and rows in a planar dimension above the substrate, wherein the active transistor cells have cell heights in a column direction of the planar dimension and cell widths in a row direction of the planar dimension, the row direction being orthogonal to the column direction, wherein the active transistor cells include nanosheet active regions with widths in the column direction of the planar dimension and lengths in the row direction of the planar dimension, wherein a set of active transistor cells in a column by row arrangement includes at least:
a first active transistor cell in a first row of a first column in the set, the first active transistor cell having a first cell height and a first cell width;
a second active transistor cell in a second row of the first column in the set, the second active transistor cell having the first cell height and the first cell width;
a third active transistor cell in a first row of a second column in the set, the third active transistor cell having a second cell height and a second cell width, wherein the second cell height is different from the first cell height; and
a fourth active transistor cell in a second row of the second column in the set, the fourth active transistor cell having a third cell height and the second cell width, wherein the third cell height is less than the second cell height and different than the first cell height.

14. The apparatus of claim 13, wherein the second cell height plus the third cell height is equal to twice the first cell height.

15. The apparatus of claim 13, wherein the set of active transistor cells in the column by row arrangement further includes:
a fifth active transistor cell in a third row of the first column in the set, the fifth active transistor cell having the first cell height and the first cell width.

16. The apparatus of claim 15, wherein the set of active transistor cells in the column by row arrangement further includes:
a sixth active transistor cell in a third row of the second column in the set, the sixth active transistor cell having a fourth cell height and the second cell width, the fourth cell height being different than at least one of the second cell height and the third cell height.

17. The apparatus of claim 13, further comprising at least one dummy gate structure oriented in the column direction along a border between the first column and the second column.

18. A semiconductor apparatus, comprising:
a substrate;
a plurality of active transistor cells formed on the substrate, the active transistor cells being arranged in columns and rows in a planar dimension above the substrate, wherein the active transistor cells have cell heights in a column direction of the planar dimension and cell widths in a row direction of the planar dimension, the row direction being orthogonal to the column direction, wherein the active transistor cells include nanosheet active regions with widths in the column direction and lengths in the row direction, wherein a set of active transistor cells in a column by row arrangement includes:
a first column of template active transistor cells, wherein a number of rows of template active transistor cells in the first column is at least two, and wherein a total height of the first column is a sum of the cell heights for the template active transistor cells in the first column, the cell heights of the template active transistor cells in the first column being substantially the same; and
a second column of flexible active transistor cells, wherein a number of rows of flexible active transistor cells in the second column is at least two and at most equal to the number of rows of template active transistor cells in the first column, at least one flexible active transistor cell in the second column having a cell height different from a cell height of at least one other flexible active transistor cell in the second column, and wherein a total height of the second column is a sum of the cell heights for the flexible active transistor cells in the second column, the total height of the second column being equal to the total height of the first column; and
a metal routing layer positioned above the active transistor cells and the substrate, wherein the metal routing layer includes:
at least one power grid route oriented in the row direction continuously passing over the first column and the second column; and
a plurality of signal routes oriented in the row direction continuously passing over the first column and the second column.

19. The apparatus of claim 18, wherein a number of signal routes passing over the first column and the second column is constant between a first row of the first column and a first row of the second column and constant between a second row of the first column and a second row of the second column.

20. The apparatus of claim 18, wherein the at least one power grid route is shared between a first row of the first column, a first row of the second column, a second row of the first column, and a second row of the second column.
